(19) United States
(12) Patent Application Publication
(10) Pub. No.: US 2025/0062178 A1
(43) Pub. Date: Feb. 20, 2025

(54) SEMICONDUCTOR PACKAGE INCLUDING A FILM SUBSTRATE

(71) Applicant: SAMSUNG ELECTRONICS CO., LTD, SUWON-SI (KR)

(72) Inventors: Kyoungsuk YANG, Suwon-si (KR); Jeongkyu HA, Suwon-si (KR)

(21) Appl. No.: 18/748,463

(22) Filed: Jun. 20, 2024

(30) Foreign Application Priority Data
Aug. 17, 2023 (KR) 10-2023-0107337

(51) Int. Cl. H01L 23/36; H01L 23/00; H01L 23/498

(52) U.S. Cl. CPC H01L 23/36; H01L 23/49838; H01L 24/32; H01L 23/4985; H01L 2224/32221

(57) ABSTRACT

A semiconductor package includes: a film substrate having a chip mounting area, and extending in a first direction; a plurality of wirings provided on the film substrate, and including a metal lead portion having an inner lead bonding portion and an outer lead bonding portion, wherein the inner lead bonding portion is at least partially disposed within the chip mounting area, and the outer lead bonding portion from the inner lead bonding portion; an upper insulating layer covering the plurality of wirings, and having a mounting area opening that exposes at least a portion of the inner lead bonding portion; a semiconductor chip disposed on the chip mounting area of the film substrate, and bonded to the exposed inner lead bonding portion; and a heat dissipation member on the upper insulating layer, and including a plurality of first extension patterns extending within the through opening to cover the semiconductor chip.

### CROSS-REFERENCE TO RELATED APPLICATION

This application claims priority under 35 U.S.C. § 119 to Korean Patent Application No. 10-2023-0107337, filed on Aug. 17, 2023 in the Korean Intellectual Property Office (KIPO), the disclosure of which is incorporated by reference herein in its entirety.

### TECHNICAL FIELD

Example embodiments of the present inventive concept relate to a semiconductor package. More particularly, example embodiments of the present inventive concept relate to a semiconductor package including a film substrate.

### Discussion of the Related Art

A chip on film (COF) semiconductor package may be formed by bonding a semiconductor chip to a metal lead portion of a film substrate. Generally, a semiconductor chip that is formed on the film substrate may be covered with a metal tape to dissipate heat that is generated from the film substrate and the semiconductor chip. As the metal tape is used, manufacturing costs may increase and poor contact points may occur due to repulsive force arising from high rigidity of the metal material. When a polyimide tape (PI tape) is used to solve the poor contact points, warping may occur due to low rigidity and a wave shape may also occur in the PI tape.

### SUMMARY

According to embodiments of the present inventive concept, a semiconductor package includes: a film substrate having a chip mounting area, and extending in a first direction, wherein the film substrate has a first side and a second side that face each other; a plurality of wirings provided on the film substrate, wherein the plurality of wirings includes a metal lead portion having an inner lead bonding portion and an outer lead bonding portion, wherein the inner lead bonding portion is at least partially disposed within the chip mounting area, and the outer lead bonding portion extends toward at least one of the first side or the second side from the inner lead bonding portion; an upper insulating layer provided on the film substrate and covering the plurality of wirings, wherein the upper insulating layer has a mounting area opening that exposes at least a portion of the inner lead bonding portion on the chip mounting area; a semiconductor chip disposed on the chip mounting area of the film substrate, and bonded to and electrically connected to the exposed inner lead bonding portion; and a heat dissipation member provided on the upper insulating layer, and having a through opening that exposes the mounting area opening, wherein the heat dissipation member includes a plurality of first extension patterns extending in a second direction that is different from the first direction within the through opening to cover the semiconductor chip.

According to embodiments of the present inventive concept, a semiconductor package includes: a film substrate having a chip mounting area, and having an upper surface and a lower surface opposite to each other, wherein the film substrate extends in a first direction, and has a first side and a second side that face each other; a plurality of wirings provided on the upper surface of the film substrate, wherein the plurality of wirings includes a metal lead portion having an inner lead bonding portion and an outer lead bonding portion, wherein the inner lead bonding portion is at least partially disposed within the chip mounting area, and the outer lead bonding portion extends toward at least one of the first side or the second side from the inner lead bonding portion; an upper insulating layer provided on the upper surface of the film substrate and covering the plurality of wirings, wherein the upper insulating layer has a plurality of pad openings and a mounting area opening, wherein the plurality of pad openings expose at least a portion of the outer lead bonding portion, and the mounting area opening exposes at least a portion of the inner lead bonding portion on the chip mounting area; a semiconductor chip disposed on the chip mounting area of the film substrate, and bonded to and electrically connected to the exposed inner lead bonding portion; and a heat dissipation member provided on the upper insulating layer, and having a through opening that exposes the mounting area opening, wherein the heat dissipation member includes a plurality of first extension patterns extending in a second direction that is different from the first direction within the through opening to cover the semiconductor chip.

According to embodiments of the present inventive concept, a semiconductor package includes: a film substrate having a chip mounting area, and extending in a first direction, wherein the film substrate has a first side and a second side that extend in the first direction and face each other; a plurality of wirings provided on the film substrate, wherein the plurality of wirings includes a metal lead portion having an inner lead bonding portion and an outer lead bonding portion, wherein the inner lead bonding portion is at least partially disposed within the chip mounting area, and the outer lead bonding portion extends toward at least one of the first side or the second side from the inner lead bonding portion; an upper insulating layer provided on the film substrate and covering the plurality of wirings, wherein the upper insulating layer has a plurality of pad openings and a mounting area opening, wherein the plurality of pad openings expose at least a portion of the outer lead bonding portion, and the mounting area opening exposes at least a portion of the inner lead bonding portion on the chip mounting area; a semiconductor chip disposed on the chip mounting area of the film substrate, and bonded to and electrically connected to the exposed inner lead bonding portion; and a heat dissipation member provided on the upper insulating layer, and having a through opening that exposes the mounting area opening, wherein the heat dissipation member includes a plurality of first extension patterns and at least one second extension pattern, wherein the plurality of first extension patterns extends in a second direction that is different from the first direction within the through opening to cover the semiconductor chip, and the at least one second extension pattern extends in the first direction to intersect the plurality of first extension patterns within the through opening.

### BRIEF DESCRIPTION OF THE DRAWINGS

The above and other features of the present inventive concept will become more apparent by describing in detail example embodiments thereof, with reference to the accompanying drawings, in which:

FIG. 1 is a plan view illustrating a semiconductor device in accordance with example embodiments of the present inventive concept.

FIG. 2 is a plan view illustrating the semiconductor package of FIG. 1.

FIG. 3 is a cross-sectional view taken along the line A-A′ in FIG. 2.

FIG. 4 is a cross-sectional view taken along the line B-B′ FIG. 2.

FIGS. 5, 6 and 7 are plan views illustrating semiconductor packages with modified heat dissipation members in accordance with example embodiments of the present inventive concept.

### DETAILED DESCRIPTION OF EXAMPLE EMBODIMENTS

Hereinafter, example embodiments of the present inventive concept will be explained in detail with reference to the accompanying drawings.

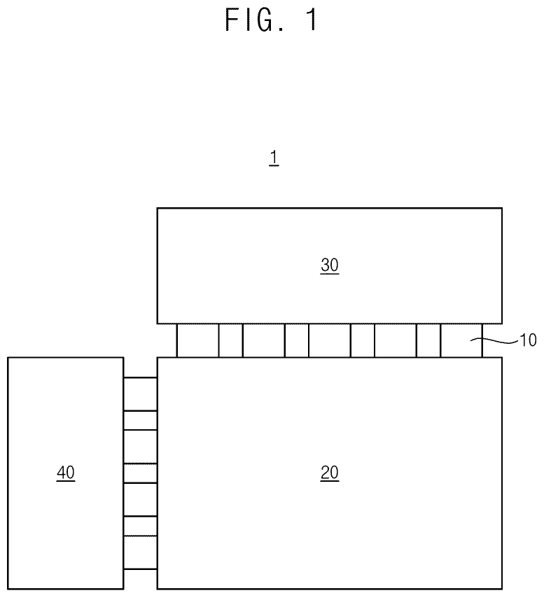

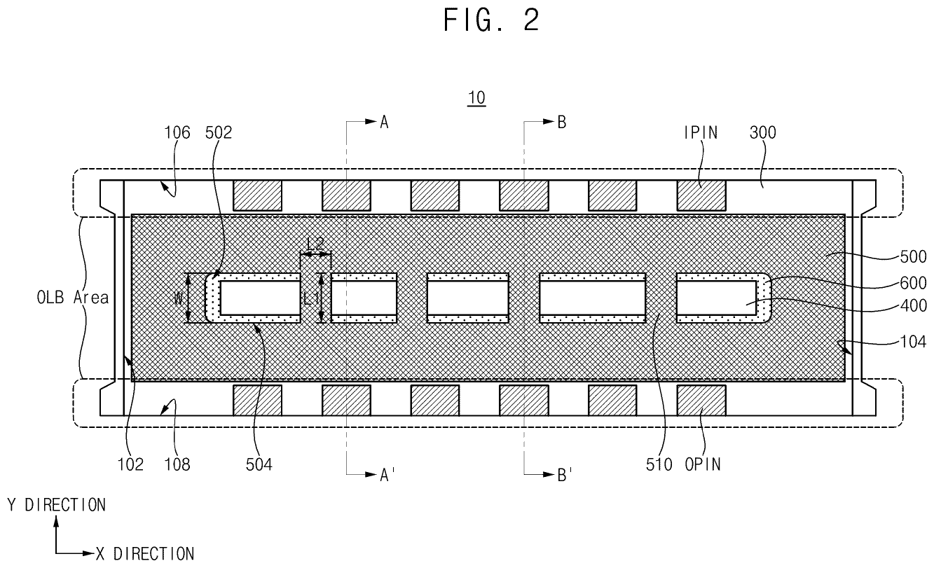

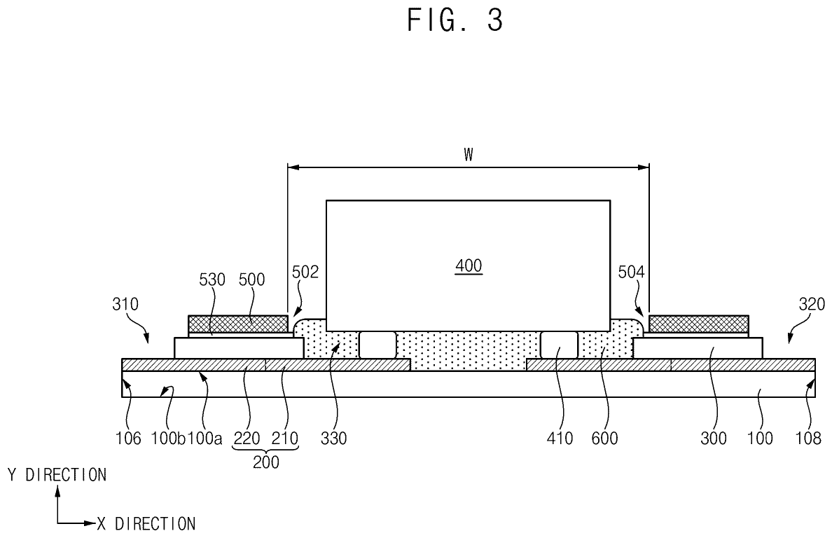

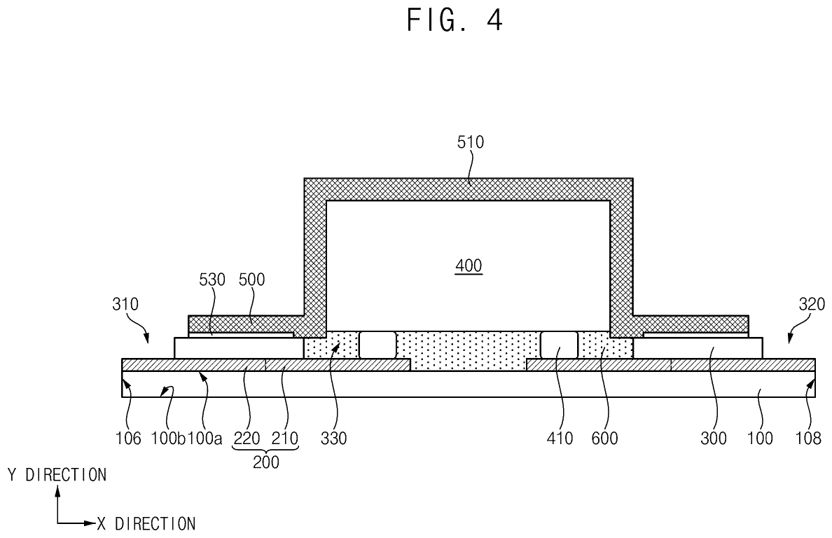

FIG. 1 is a plan view illustrating a semiconductor device in accordance with example embodiments of the present inventive concept. FIG. 2 is a plan view illustrating the semiconductor package of FIG. 1. FIG. 3 is a cross-sectional view taken along the line A-A′ in FIG. 2. FIG. 4 is a cross-sectional view taken along the line B-B′ FIG. 2.

Referring to FIGS. 1 to 4, a semiconductor device 1 may include a film-type semiconductor package 10, first and second semiconductor substrates 30 and 40, and a display panel 20. The first semiconductor substrate 30 may include a source drive substrate. The second semiconductor substrate 40 may include a gate drive substrate.

The source drive substrate 30 and the gate drive substrate 40 may provide signals to the display panel 20 so that an image is displayed by the pixels of the display panel 20. The display panel 20 may display an image based on the received signal. The film-type semiconductor package 10 may receive signals that are output from the source drive substrate 30 and the gate drive substrate 40 and may transmit the signals to the display panel 20.

In example embodiments of the present invention, the semiconductor package 10 may include a film substrate 100, a plurality of wirings, which are provided on the film substrate 100 and have a metal lead portion 200, an upper insulating layer 300, which is provided on the metal lead portion, a semiconductor chip 400, which is disposed on the metal lead portion 200, and a heat dissipation member 500, which is provided on the upper insulating layer 300. The semiconductor package 10 may electrically connect the semiconductor chip 400, the source drive substrate 30, the gate drive substrate 40, and the display panel 20 to each other through the metal lead portion 200. For example, the semiconductor package 10 may be a chip on film (COF) semiconductor package.

In example embodiments of the present inventive concept, the film substrate 100 may have an upper surface 100a and a lower surface 100b that is opposite to the upper surface 100a. The film substrate 100 may have a front surface 102 and a rear surface 104 that are spaced apart in a first direction (X direction) and extending in a second direction (Y direction) that are substantially perpendicular to the first direction (X direction). The film substrate 100 may have first and second sides 106 and 108 which face each other. The film substrate 100 may have a chip mounting region on which the semiconductor chip 400 is mounted. For example, the film substrate 100 may be a film-type printed circuit board (PCB). The film substrate 100 may be, for example, a polyimide substrate.

In example embodiments of the present inventive concept, the metal lead portion 200 may include an inner lead bonding portion (ILB) 210 and an outer lead bonding portion (OLB) 220. The outer lead bonding portion 220 may be provided in an outer area (OLB Area) that extends along the first direction (X direction) on a peripheral region of the film substrate 100. The inner lead bonding portion 210 and the outer lead bonding portion 220 may extend on the upper surface 100a in a longitudinal direction (Y direction) of the film substrate 100. The metal lead portion 200 may be arranged in various ways on the film substrate 100 depending on the design.

At least a portion of the inner lead bonding portion 210 may be disposed within the chip mounting region. The inner lead bonding portion 210 may be connected to conductive patterns 410, for example, bumps that are formed on the semiconductor chip 400. The inner lead bonding portion 210 may be electrically connected to the semiconductor chip 400 via the conductive patterns 410. The inner lead bonding portion 210 may extend from the outer lead bonding portion 220 in the longitudinal direction (e.g., the X-direction) of the film substrate 100.

The outer lead bonding portion 220 may be electrically connected to the display panel 20, the source drive substrate 30, or the gate drive substrate 40.

The outer lead bonding portion 220 may extend from the inner lead bonding portion 210 to at least one of the first side 106 or the second side 108. The outer lead bonding portion 220 may extend from the inner lead bonding portion 210 in the longitudinal direction (e.g., the X-direction) of the film substrate 100.

At least a portion of the outer lead bonding portion 220 may serve as input pins (IPIN) and output pins (OPIN) for transmitting and receiving electrical signals with each of the display panel 20, the source drive substrate 30, and the gate drive substrate 40. The outer lead bonding portion 220, which functions as input/output pins (IPIN, OPIN), may be arranged along the outer area (OLB Area) on the film substrate 100. The input pins IPIN may be arranged along the first side 106 of the film substrate 100, and the output pins OPIN may be arranged along the second side 108 that is opposite to the first side 106.

For example, the metal lead portion 200 may include, for example, copper (Cu), aluminum (Al), tungsten (W), nickel (Ni), molybdenum (Mo), gold (Au), silver (Ag), chromium (Cr), tin (Sn), titanium (Ti), or an alloy thereof.

In example embodiments of the present inventive concept, the upper insulating layer 300 may cover the plurality of wirings on the upper surface 100a of the film substrate 100. The upper insulating layer 300 may be provided on the metal lead portion 200. For example, the upper insulating layer 300 may cover a portion of the metal lead portion 200. The upper insulating layer 300 may be provided on a boundary area where the inner lead bonding portion 210 and the outer lead bonding portion 220 meet each other.

The upper insulating layer 300 may expose at least a portion of the outer lead bonding portion 220. The upper insulating layer 300 may expose the input pins (IPIN) and output pins (OPIN) of the outer lead bonding portion 220. The upper insulating layer 300 may have an annular shape with a preset gap. The semiconductor chip 400 may be mounted on the metal lead portion 200 through an opening of the annular shape of the upper insulating layer 300.

The upper insulating layer 300 may provide a plurality of openings that expose the at least a portion of the outer lead bonding portion 220, and each of the semiconductor chip 400, display panel 20, the source drive substrate 30 and the gate drive substrate 40 may be electrically connected to the outer lead bonding portion 220 through the plurality of openings. For example, the plurality of openings may expose the input pins (IPIN) and output pins (OPIN) of the outer lead bonding portion 220.

The upper insulating layer 300 may include a plurality of pad openings 310 and 320 that expose at least a portion of the outer lead bonding portion 220 along at least one of the first side 106 or the second side 108. The upper insulating layer 300 may include a mounting area opening 330 that exposes at least a portion of the inner lead bonding portion 210 in the chip mounting region. The inner lead bonding portion 210 may be electrically connected to the semiconductor chip 400 through the mounting area opening 330. For example, the mounting area opening 330 may extend along the first direction (X direction) of the film substrate 100.

The upper insulating layer 300 may include first pad openings 310, which expose at least a portion of the outer lead bonding portion 220 along the first side 106, and second pad openings 320, which expose at least a portion of the outer lead bonding portion 220 along the second side 108. The outer lead bonding portion 220 may be electrically connected to the display panel 20, the source drive substrate 30 and the gate drive substrate 40, respectively, through the first and second pad openings 310 and 320. For example, the first and second pad openings 310 and 320 may be arranged along the first direction (X direction) of the film substrate 100.

For example, the upper insulating layer 300 may include a polymer, a dielectric layer, etc. For example, the upper insulating layer 300 may include polyimide (PI), lead oxide (PbO), polyhydroxystyrene (PHS), or novolac (NOVOLAC). The upper insulating layer 300 may be formed by a vapor deposition process, spin coating process, etc.

In example embodiments of the present inventive concept, the semiconductor chip 400 may be mounted on the metal lead portion 200. The semiconductor chip 400 may be bonded to and electrically connected to the inner lead bonding portion 210 of the metal lead portion 200. For example, the semiconductor chip 400 may be bonded to the inner lead bonding portion 210 through a thermal compression process.

The semiconductor chip 400 may include a plurality of conductive patterns 410 that are formed on a lower surface thereof. The semiconductor chip 400 may be mounted on the metal lead portion 200 via the conductive patterns 410 to be electrically connected to the display panel 20, the source drive substrate 30, or the gate drive substrate 40. The conductive patterns 410 of the semiconductor chip 400 may be respectively bonded and electrically connected to the inner lead bonding portion 210 of the metal lead portion 200. The semiconductor chip 400 may be electrically connected to the input/output pins (IPIN, OPIN) of the metal lead portion 200.

The semiconductor chip 400 may have a preset length along the first direction (X direction). The preset length of the semiconductor chip 400 may be smaller than a length of the annular-shaped inner portion of the metal lead portion 200, and the semiconductor chip 400 may be inserted into the annular-shaped inner portion to be bonded to the metal lead portion 200.

In example embodiments of the present inventive concept, the heat dissipation member 500 may be provided on the upper insulating layer 300. The heat dissipation member 500 may cover at least a portion of the semiconductor chip 400 on the upper insulating layer 300. The heat dissipation member 500 may absorb and dissipate heat that is generated from the plurality of wiring or the film substrate on the upper insulating layer 300. The heat dissipation member 500 may protect the plurality of wirings from the outside.

The heat dissipation member 500 may expose the chip mounting area of the film substrate 100. The heat dissipation member 500 may have a through opening 502 that exposes the mounting area opening 330 of the upper insulating layer 300. The heat dissipation member 500 may be provided on the metal lead portion 200 through the through opening 502 of the heat dissipation member 500. The heat dissipation member 500 may expose the semiconductor chip 400 to the outside through the through opening 502 of the heat dissipation member and may dissipate heat that is generated from the semiconductor chip 400 to the outside. For example, the through opening 502 may have a preset width (W).

When viewed in plan view, the heat dissipation member 500 may be provided within the area of the upper insulating layer 300. The heat dissipation member 500 may expose at least a portion of the outer lead bonding portion 220. The heat dissipation member 500 may expose the input pins (IPIN) and output pins (OPIN) of the outer lead bonding portion 220.

The heat dissipation member 500 may include a polymer material that is the same as the upper insulating layer 300. In addition, the heat dissipation member 500 may include a material that is different from the upper insulating layer 300. For example, the heat dissipation member 500 may include a polyimide tape (PI tape). For example, the heat dissipation member 500 may include polyimide (PI), lead oxide (PbO), polyhydroxystyrene (PHS), or novolac (NOVOLAC). The heat dissipation member 500 may be formed by a vapor deposition process, spin coating process, etc.

The heat dissipation member 500 might not include a metal material. The heat dissipation member 500 may have relatively low rigidity because the heat dissipation member 500 includes the polyimide tape and does not include the metal material. Since the heat dissipation member 500 has the relatively low rigidity, the heat dissipation member 500 may cover at least a portion of the semiconductor chip 400 on the upper insulating layer 300 to thereby prevent a contact failure.

The heat dissipation member 500 may include a plurality of first extension patterns 510. The plurality of first extension patterns 510 may extend in the second direction (Y direction) within the through opening 502. The plurality of first extension patterns 510 may extend from an inner surface 504 of the through opening 502, respectively. Each of the plurality of first extension patterns 510 may have a first length L1 in the second direction (Y direction). For example, the first length L1 may be equal to the preset width W of the through opening 502.

The plurality of first extension patterns 510 may generate friction or adhesive force with the semiconductor chip 400. The plurality of first extension patterns 510 may have a number sufficient to generate the friction force or the adhesive force with the semiconductor chip 400. Since the plurality of first extension patterns 510 causes the frictional force or adhesive force with the semiconductor chip 400, the upper insulating layer 300 may be prevented from being distorted. For example, the number of the plurality of first extension patterns 510 may range from 2 to 10.

Each of the plurality of first extension patterns 510 may have a second length L2 in the first direction (X direction). The second length L2 may be determined to be sufficient to prevent the distortion phenomenon through the friction or adhesive force with the semiconductor chip 400.

The plurality of first extension patterns 510 may extend between opposed inner surfaces 504 of the through openings 502. Because the plurality of first extension patterns 510 extend between the opposed inner surfaces 504 of the through opening 502, the plurality of first extension patterns 510 may generate tension. The plurality of first extension patterns 510 may prevent a wave shape from occurring in the through opening 502 through the tension of the plurality of first extension patterns 510. For example, the wave shape may include a wrinkle shape.

In example embodiments of the present inventive concept, the semiconductor package 10 may further include a first adhesive member 530 that is configured to adhere the heat dissipation member 500 to the upper insulating layer 300. The first adhesive member 530 can fix the heat dissipation member 500 onto the upper insulating layer 300.

For example, the first adhesive member 530 may include an epoxy mold compound (EMC). For example, the first adhesive member 530 may include epoxy resin, UV resin, polyurethane resin, silicone resin, silica fillers, etc.

In example embodiments of the present inventive concept, the semiconductor package 10 may further include an electronic element. The electronic element may be bonded to the metal lead portion 200. The electronic element may be bonded to the metal lead portion 200 through an opening that is provided in the upper insulating layer 300. For example, the electronic element may perform various functions as a surface mount device. The electronic elements may include active elements, passive elements, and other semiconductor chips.

In example embodiments of the present inventive concept, the semiconductor package 10 may further include a second adhesive member 600 that fills a space between the semiconductor chip 400 and the metal lead portion 200. The second adhesive member 600 may fill the space between the semiconductor chip 400, the film substrate 100, the metal lead portion 200, and the upper insulating layer 300. The second adhesive member 600 may fill the space between the upper insulating layer 300, the semiconductor chip 400, and the heat dissipation member 500 on the film substrate 100. The second adhesive member 600 may at least partially surround the conductive patterns 410 of the semiconductor chip 400 and may secure the semiconductor chip 400 on the metal lead portion 200.

For example, the second adhesive member 600 may include an epoxy mold compound (EMC). The second adhesive member 600 may include, for example, epoxy resin, UV resin, polyurethane resin, silicone resin, silica fillers, etc.

In example embodiments of the present inventive concept, the source drive substrate 30, the gate drive substrate 40, and the display panel 20 may be mounted on the metal lead portion 200, respectively. Each of the source drive substrate 30, the gate drive substrate 40, and the display panel 20 may be bonded to and electrically connected to the outer lead bonding portion 220 of the metal lead portion 200. For example, the source drive substrate 30, the gate drive substrate 40, and the display panel 20 may be bonded to the outer lead bonding portion 220 through a thermal compression process, respectively. For example, the source drive substrate 30, the gate drive substrate 40, and the display panel 20 may be electrically connected to the input/output pins (IPIN, OPIN) of the metal lead portion 200, respectively.

As described above, the heat dissipation member 500 may be provided on the upper insulating layer 300 and may dissipate heat that is generated from the plurality of wirings to the outside and may protect the plurality of wirings from the outside. The heat dissipation member 500 may include the polyimide tape. Since the polyimide tape does not include the metal material, the heat dissipation member 500 may have relatively low rigidity. The low rigidity of the heat dissipation member 500 may prevent poor contact from the upper insulating layer 300. The heat dissipation member 500 may reduce manufacturing costs.

Further, the heat dissipation member 500 may include the plurality of first extension patterns 510 that extend between the opposed inner surfaces 504 of the through opening 502. The plurality of first extension patterns 510 may cover the semiconductor chip 400 within the through opening 502. Since the plurality of first extension patterns 510 cover the semiconductor chip 400 within the through opening 502, the distortion of the heat dissipation member 500 may be prevented. For example, the plurality of extension patterns 510 may contact the semiconductor chip 400, which may prevent distortion of the heat dissipation member 500. The plurality of first extension patterns 510 of the heat dissipation member 500 may prevent the wave shape from occurring in the through opening 502.

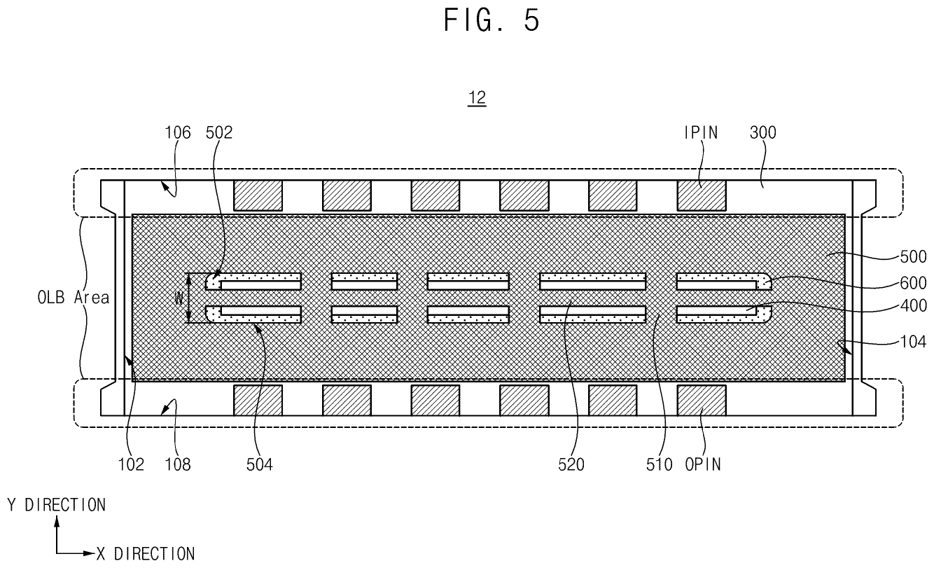

FIGS. 5 to 7 are plan views illustrating semiconductor packages with modified heat dissipation members in accordance with example embodiments of the present invention. The semiconductor packages may be the same as, substantially the same as, or similar to the semiconductor packages described with reference to FIGS. 1 to 4 except for configurations of a heat dissipation member. Thus, same reference numerals may be used to refer to the same or like elements, and any further repetitive explanation concerning the above elements will be omitted or briefly discussed.

Referring to FIG. 5, a semiconductor package 12 may include a film substrate 100, a plurality of wirings, which are provided on the film substrate 100 and have a metal lead portion 200, an upper insulating layer 300, which is provided on the metal lead portion 200, a semiconductor chip 400, which is disposed on the metal lead portion 200, and a heat dissipation member 500 that is provided on the upper insulating layer 300.

In example embodiments of the present inventive concept, the heat dissipation member 500 may be provided on the upper insulating layer 300. The heat dissipation member 500 may cover at least a portion of the semiconductor chip 400 and may be disposed on the upper insulating layer 300. The heat dissipation member 500 may have a through opening 502 that exposes a mounting area opening 330 of the upper insulating layer 300. The semiconductor chip 400 may be mounted on the metal lead portion 200 through the through opening 502 of the heat dissipation member 500 and the mounting area opening 330.

The heat dissipation member 500 may include a plurality of first extension patterns 510 and at least one second extension pattern 520 that intersects the plurality of first extension patterns 510. The plurality of first extension patterns 510 may extend in a second direction (Y direction) within the through opening 502. The second extension pattern 520 may extend in a first direction (X direction) within the through opening 502.

The plurality of first and second extension patterns 510 and 520 may generate a friction force or an adhesive force with the semiconductor chip 400. The plurality of first and second extension patterns 510 and 520 may prevent the upper insulating layer 300 from being distorted through the friction or adhesive force with the semiconductor chip 400. The plurality of first and second extension patterns 510 and 520 may prevent a wave shape from occurring in the through opening 502 through tension.

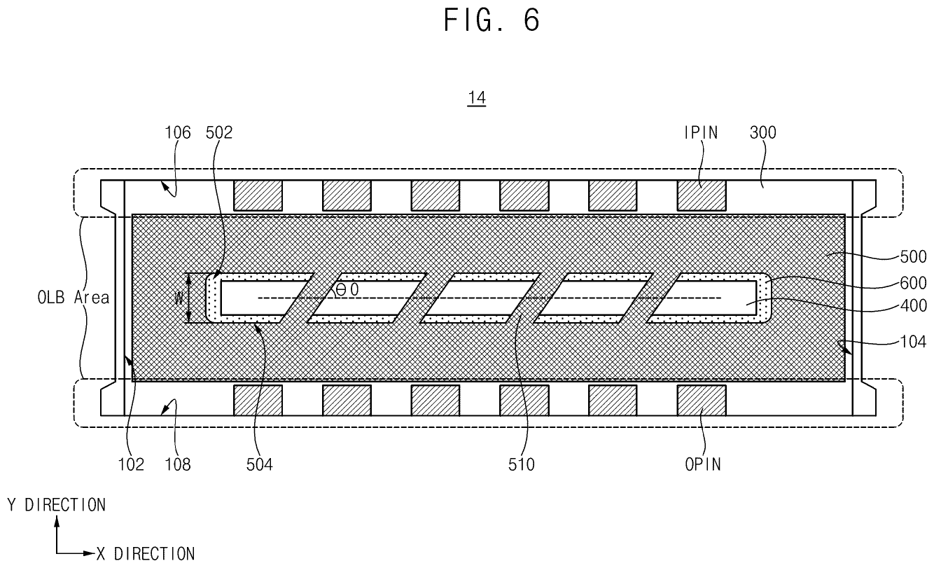

Referring to FIG. 6, a semiconductor package 14 may include a film substrate 100, a plurality of wirings, which are provided on the film substrate 100 and have a metal lead portion 200, an upper insulating layer 300, which is provided on the metal lead portion 200, a semiconductor chip 400, which is disposed on the metal lead portion 200, and a heat dissipation member 500 that is provided on the upper insulating layer 300.

The heat dissipation member 500 may include a plurality of first extension patterns 510. The plurality of first extension patterns 510 may extend in an oblique direction within a through opening 502 to have preset angles θ0 with respect to a first direction (X direction). For example, each of the first extension patterns 510 may have slanted side surfaces. Each of the plurality of first extension patterns 510 may extend from an inner surface 504 of the through opening 502. The plurality of first extension patterns 510 may extend in the same directions. For example, each of the preset angles θ0 may be within a range of about 20 degrees to about 70 degrees with respect to the first direction (X direction).

When the plurality of first extension patterns 510 have the preset angles θ0, the plurality of first extension patterns 510 may increase the friction or adhesive force with the semiconductor chip 400. When a force is applied to the heat dissipation member 500 in a diagonal direction that is between the first direction (X direction) and the second direction (Y direction), the plurality of first extension patterns 510 may effectively prevent the distortion of the upper insulating layer 300 through the preset angles θ0.

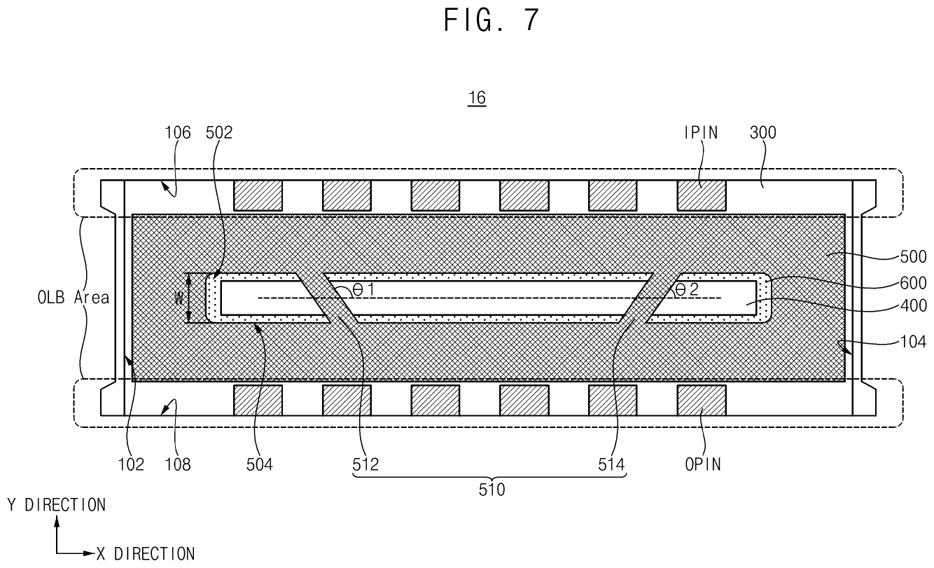

Referring to FIG. 7, a semiconductor package 16 may include a film substrate 100, a plurality of wirings, which are provided on the film substrate 100 and have a metal lead portion 200, an upper insulating layer 300, which is provided on the metal lead portion 200, a semiconductor chip 400, which is disposed on the metal lead portion 200, and a heat dissipation member 500 that is provided on the upper insulating layer 300.

The heat dissipation member 500 may include a plurality of first extension patterns 510. The first extension patterns 510 include a first pattern 512 and a second pattern 514. The first pattern 512 extends in a direction to have a first angle θ1 with respect to a first direction (X direction), and the second pattern 514 extends in a direction to have a second angle θ2 with respect to the first direction (X direction). The first angle θ1 may be different from the second angle θ2. For example, the first angle θ1 may be formed between an inner side of the first pattern 512 and an imaginary line extending in the first direction (X direction). For example, the second angle θ2 may be formed between an outer side of the second pattern 514 and the imaginary line extending in the first direction (X direction). For example, when the first angle θ1 has an obtuse angle, the second angle θ2 may have an acute angle. For example, the first angle θ1 may be within a range of about 110 degrees to about 160 degrees. The second angle θ2 may be within a range of about 20 degrees to about 70 degrees. In addition, when the second angle θ2 has an obtuse angle, the first angle θ1 may have an acute angle. The first pattern 512 may extend in a direction different from that of the second pattern 514. For example, from a plan view, the first pattern 512 may have a negative slope direction, and the second pattern 514 may have a positive slope direction.

When the first and second patterns 512 and 514 extend in different directions, the first and second patterns 512 and 514 may increase the friction or adhesive force with the semiconductor chip 400. When a force is applied in a diagonal direction between the first direction (X direction) and the second direction (Y direction) on the heat dissipation member 500, the first and second patterns 512 and 514 may effectively prevent the warping phenomenon of the upper insulating layer 300 through the first and second angles θ1 and 02.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor package, comprising:
a film substrate having a chip mounting area, and extending in a first direction, wherein the film substrate has a first side and a second side that face each other;
a plurality of wirings provided on the film substrate, wherein the plurality of wirings includes a metal lead portion having an inner lead bonding portion and an outer lead bonding portion, wherein the inner lead bonding portion is at least partially disposed within the chip mounting area, and the outer lead bonding portion extends toward at least one of the first side or the second side from the inner lead bonding portion;
an upper insulating layer provided on the film substrate and covering the plurality of wirings, wherein the upper insulating layer has a mounting area opening that exposes at least a portion of the inner lead bonding portion on the chip mounting area;
a semiconductor chip disposed on the chip mounting area of the film substrate, and bonded to and electrically connected to the exposed inner lead bonding portion; and
a heat dissipation member provided on the upper insulating layer, and having a through opening that exposes the mounting area opening, wherein the heat dissipation member includes a plurality of first extension patterns extending in a second direction that is different from the first direction within the through opening to cover the semiconductor chip.

2. The semiconductor package of claim 1, wherein the heat dissipation member further includes at least one second extension pattern extending in the first direction to intersect the plurality of first extension patterns within the through opening.

3. The semiconductor package of claim 1, wherein the plurality of first extension patterns extend in the second direction at preset angles with respect to the first direction within the through opening.

4. The semiconductor package according to claim 3, wherein each of the preset angles is within a range of about 20 degrees to about 70 degrees.

5. The semiconductor package of claim 1, wherein the plurality of first extension patterns includes:
a first pattern extending in the second direction to have a first angle with respect to the first direction; and
a second pattern extending in the second direction to have a second angle with respect to the first direction, wherein the first angle is different from the second angle.

6. The semiconductor package of claim 5, wherein, when the first angle is an obtuse angle, and the second angle is an acute angle.

7. The semiconductor package of claim 6, wherein the first angle is within a range of about 110 degrees to about 160 degrees, and the second angle is within a range of about 20 degrees to about 70 degrees.

8. The semiconductor package of claim 1, wherein a number of the plurality of first extension patterns ranges from 2 to 10.

9. The semiconductor package of claim 1, wherein the heat dissipation member includes a polyimide tape.

10. The semiconductor package of claim 1, further comprising:
an adhesive member that adhesively fixes the heat dissipation member to the upper insulating layer.

11. A semiconductor package, comprising:
a film substrate having a chip mounting area, and having an upper surface and a lower surface opposite to each other, wherein the film substrate extends in a first direction, and has a first side and a second side that face each other;
a plurality of wirings provided on the upper surface of the film substrate, wherein the plurality of wirings includes a metal lead portion having an inner lead bonding portion and an outer lead bonding portion, wherein the inner lead bonding portion is at least partially disposed within the chip mounting area, and the outer lead bonding portion extends toward at least one of the first side or the second side from the inner lead bonding portion;
an upper insulating layer provided on the upper surface of the film substrate and covering the plurality of wirings, wherein the upper insulating layer has a plurality of pad openings and a mounting area opening, wherein the plurality of pad openings expose at least a portion of the outer lead bonding portion, and the mounting area opening exposes at least a portion of the inner lead bonding portion on the chip mounting area;
a semiconductor chip disposed on the chip mounting area of the film substrate, and bonded to and electrically connected to the exposed inner lead bonding portion; and
a heat dissipation member provided on the upper insulating layer, and having a through opening that exposes the mounting area opening, wherein the heat dissipation member includes a plurality of first extension patterns extending in a second direction that is different from the first direction within the through opening to cover the semiconductor chip.

12. The semiconductor package of claim 11, wherein the heat dissipation member further includes at least one second extension pattern extending in the first direction to intersect the plurality of first extension patterns within the through opening.

13. The semiconductor package of claim 11, wherein the plurality of first extension patterns extend in the second direction at preset angles with respect to the first direction within the through opening.

14. The semiconductor package of claim 13, wherein each of the preset angles is within a range of about 20 degrees to about 70 degrees.

15. The semiconductor package of claim 11, wherein the plurality of first extension patterns includes:
a first pattern extending in the second direction to have a first angle with respect to the first direction; and
a second pattern extending in the second direction to have a second angle with respect to the first direction, wherein the first angle is different from the second angle.

16. The semiconductor package of claim 15, wherein, when the first angle is an obtuse angle, and the second angle is an acute angle.

17. The semiconductor package of claim 16, wherein the first angle is within a range of about 110 degrees to about 160 degrees, and the second angle is within a range of about 20 degrees to about 70 degrees.

18. The semiconductor package of claim 11, wherein a number of the plurality of first extension patterns ranges from 2 to 10.

19. The semiconductor package of claim 11, wherein the heat dissipation member includes a polyimide tape.

20. A semiconductor package, comprising:
a film substrate having a chip mounting area, and extending in a first direction, wherein the film substrate has a first side and a second side that extend in the first direction and face each other;
a plurality of wirings provided on the film substrate, wherein the plurality of wirings includes a metal lead portion having an inner lead bonding portion and an outer lead bonding portion, wherein the inner lead bonding portion is at least partially disposed within the chip mounting area, and the outer lead bonding portion extends toward at least one of the first side or the second side from the inner lead bonding portion;
an upper insulating layer provided on the film substrate and covering the plurality of wirings, wherein the upper insulating layer has a plurality of pad openings and a mounting area opening, wherein the plurality of pad openings expose at least a portion of the outer lead bonding portion, and the mounting area opening exposes at least a portion of the inner lead bonding portion on the chip mounting area;
a semiconductor chip disposed on the chip mounting area of the film substrate, and bonded to and electrically connected to the exposed inner lead bonding portion; and
a heat dissipation member provided on the upper insulating layer, and having a through opening that exposes the mounting area opening, wherein the heat dissipation member includes a plurality of first extension patterns and at least one second extension pattern, wherein the plurality of first extension patterns extends in a second direction that is different from the first direction within the through opening to cover the semiconductor chip, and the at least one second extension pattern extends in the first direction to intersect the plurality of first extension patterns within the through opening.
